(19) United States
(12) Patent Application Publication
(10) Pub. No.: US 2024/0136319 A1
(43) Pub. Date: Apr. 25, 2024

(54) SEMICONDUCTOR MODULE, SEMICONDUCTOR DEVICE, AND VEHICLE

(71) Applicant: FUJI ELECTRIC CO., LTD., Kawasaki-shi (JP)

(72) Inventors: Mai SAITO, Kawasaki-shi (JP); Daiki YOSHIDA, Kawasaki-shi (JP)

(73) Assignee: FUJI ELECTRIC CO., LTD., Kawasaki-shi (JP)

(21) Appl. No.: 18/454,994

(22) Filed: Aug. 23, 2023

(30) Foreign Application Priority Data
Oct. 20, 2022 (JP) 2022-168966

(51) Int. Cl. H01L 23/00; H01L 23/31

(52) U.S. Cl. CPC H01L 24/40; H01L 23/3135; H01L 24/05; H01L 24/37; H01L 23/3735; H01L 24/06; H01L 24/32; H01L 24/48; H01L 24/49; H01L 24/73; H01L 2224/05553; H01L 2224/05554; H01L 2224/0603; H01L 2224/06051; H01L 2224/06181; H01L 2224/32225; H01L 2224/37012; H01L 2224/37147; H01L 2224/40227; H01L 2224/40991; H01L 2224/48227; H01L 2224/49175; H01L 2224/73221; H01L 2224/73263; H01L 2224/73265; H01L 2924/13055; H01L 2924/13091

(57) ABSTRACT

A semiconductor module includes a circuit board having a semiconductor element mounted thereon, a lead including a first bonding portion bonded to the semiconductor element via a bonding material and a wiring portion connected to the first bonding portion, and a sealing material that seals the semiconductor element and the lead. The first bonding portion has first and second side surfaces that face each other. The wiring portion has a bent portion connected to the first bonding portion at a side of the first bonding portion at which the first side surface is located. The bent portion is bent at a border between the first bonding portion and the bent portion in a direction away from a lower surface of the first bonding portion. The border is located between the first and second side surfaces of the first bonding portion in a plan view of the lead.

### CROSS-REFERENCE TO RELATED APPLICATION

This application is based upon and claims the benefit of priority to Japanese Patent Application No. 2022-168966, Filed on Oct. 21, 2022, the entire contents of which are incorporated herein by reference.

### FIELD

The present invention relates to a semiconductor module, a semiconductor device, and a vehicle.

### BACKGROUND

Some power conversion devices such as an inverter device include a semiconductor device having a circuit board on which a semiconductor element such as an insulated gate bipolar transistor (IGBT), a power metal oxide semiconductor field effect transistor (power MOSFET), and a free wheeling diode (FWD) is mounted. The circuit board includes a wiring board in which a conductor pattern is provided on a surface of an insulating substrate, and a circuit component such as a semiconductor element disposed on the wiring board.

In this type of semiconductor device, a conductor plate called a lead or the like may be used as a conductive member that electrically connects an electrode provided on a surface (upper surface) on a side opposite to a surface facing a wiring board side in electrodes of the semiconductor element and the conductor pattern of the wiring board.

In the semiconductor device in which the electrode of the semiconductor element and the conductor pattern of the wiring board are electrically connected using the lead, various measures for reducing stress on a bonding portion between the electrode of the semiconductor element and the lead have been proposed.

For example, JP 2018-46164 A describes a semiconductor device in which a lead frame (lead) includes a bonding portion in contact with an electrode of a semiconductor element, a bonding portion in contact with a conductor pattern of a wiring board, and a wiring portion connecting the bonding portions together, and a width of the bonding portions is made larger than a width of the wiring portion.

In addition, for example, JP 2018-98283 A describes a semiconductor device in which a metal wiring board (lead) electrically connected to an upper surface electrode provided on an upper surface of a semiconductor element has a bonding portion parallel to an upper surface portion of the semiconductor element and a rising portion connected to a first end portion of the bonding portion and extending in a direction away from the upper surface of the semiconductor element, and the rising portion does not overlap a gate runner that divides the upper surface electrode into a plurality of sections on the upper surface of the semiconductor element in a plane parallel to the upper surface of the semiconductor element.

In addition, for example, JP 2007-288095 A describes a semiconductor device in which a metal film formed on an electrode surface of a semiconductor chip (semiconductor element) to which a lead frame (lead) is bonded is thickened to 30 μm or more.

### SUMMARY OF THE INVENTION

In the semiconductor device described above, for the lead electrically connecting the electrode of the semiconductor element and the conductor pattern of the wiring board, it is preferable to increase a connection area of the lead with the electrode of the semiconductor element so that, for example, heat generated in the semiconductor element is easily dissipated via the lead.

In the bonding portion of the lead in contact with the electrode of the semiconductor element, the planar shape of a surface facing the electrode is rectangular. In addition, an end portion on the bonding portion side in contact with the electrode of the semiconductor element in the wiring portion connecting the two bonding portions together in the lead is connected to one side surface of the bonding portion, and the end portion of the wiring portion connected to the side surface of the bonding portion is bent. When the bonding portion of such a lead is bonded to the electrode of the semiconductor element with a bonding material such as solder, the angle of a fillet of the bonding material generated at the position of the wiring portion extended from the side surface of the bonding portion and bent is larger than the angle of a fillet generated on a side surface of the bonding material.

However, when the angle of the fillet of the bonding material increases, stress applied to a triple point where an insulating layer provided on the upper surface of the semiconductor element so as to surround the electrode, the bonding material such as solder, and a sealing material that seals the semiconductor element and the lead frame come into contact with each other increases, and a crack may occur from the triple point.

The present invention has been made in view of the above, and it is an object of the present invention to suppress the occurrence of a crack in a semiconductor module including a semiconductor element and a lead bonded to an electrode of the semiconductor element with a bonding material.

A semiconductor module according to one aspect of the present invention includes: a circuit board on which a semiconductor element is mounted; a lead bonded to an electrode on an upper surface of the semiconductor element with a bonding material; and a sealing material that seals the semiconductor element and the lead, in which the lead includes a bonding portion bonded to the electrode and a wiring portion connected to a first side surface of the bonding portion and bent in a direction opposite to a lower surface of the bonding portion facing the electrode of the semiconductor element, and a rising position of a bent portion of the wiring portion in the lower surface of the bonding portion is located between a position of the first side surface of the bonding portion and a position of a second side surface of the bonding portion opposite to the first side surface.

According to the present invention, it is possible to suppress the occurrence of a crack in the semiconductor module including the semiconductor element and the lead bonded to the electrode of the semiconductor element with the bonding material.

### BRIEF DESCRIPTION OF THE DRAWINGS

FIG. 1 is a top view illustrating a configuration example of a semiconductor device according to an embodiment;

FIG. 2 is a cross-sectional view taken along line A-A′ of the semiconductor device in FIG. 1;

FIG. 3 is an enlarged partial top view of a region R in FIG. 1;

FIG. 4 is a cross-sectional view taken along line B-B′ of the portion illustrated in FIG. 3;

FIG. 5 is a perspective view for explaining a configuration example of a first bonding portion side of a lead according to an embodiment;

FIG. 6 is a top view for explaining a connection surface between a second main electrode of a semiconductor element and a first bonding portion;

FIG. 7 is a cross-sectional view taken along line C-C′ and a cross-sectional view taken along line D-D′ of the portion illustrated in FIG. 6;

FIG. 8 is a cross-sectional view for explaining stress generated in a semiconductor module according to an embodiment;

FIG. 9 is a perspective view for explaining a conventional example of a first bonding portion side of a lead;

FIG. 10 is a top view for explaining a connection surface between a second main electrode of a semiconductor element and a first bonding portion;

FIG. 11 is a cross-sectional view taken along line E-E′ of the portion illustrated in FIG. 10;

FIG. 12 is a cross-sectional view for explaining stress generated in a semiconductor module using a lead of a conventional example;

FIG. 13 is a drawing for explaining a relationship between a distance from a first side surface to a rising position in a lower surface of a first bonding portion of a lead and a fillet angle;

FIG. 14 is a bottom view for explaining a first example of cuts made in the lead;

FIG. 15 is a bottom view for explaining a second example of cuts made in the lead;

FIG. 16 is a bottom view for explaining a third example of cuts made in the lead; and

FIG. 17 is a schematic plan view illustrating an example of a vehicle to which the semiconductor device according to the present invention is applied.

### DESCRIPTION OF EMBODIMENTS

Hereinafter, embodiments of the present invention will be described in detail with reference to the drawings. Note that the X, Y, and Z axes in each of the drawings to be referred to are illustrated for the purpose of defining a plane and a direction in an exemplified semiconductor device or the like, and the X, Y, and Z axes are orthogonal to each other and form a right-handed coordinate system. In the following description, the X direction may be referred to as a left-right direction, the Y direction may be referred to as a front-rear direction, and the Z direction may be referred to as an up-down direction. In addition, a plane including the X axis and the Y axis may be referred to as an XY plane, a plane including the Y axis and the Z axis may be referred to as a YZ plane, and a plane including the Z axis and the X axis may be referred to as a ZX plane. These directions (front-rear, left-right, and up-down directions) and planes are words used for convenience of description, and the correspondence relationship with each of the XYZ directions may change depending on the attachment posture of the semiconductor device. For example, a heat dissipation surface side (cooler side) of the semiconductor device is referred to as a lower surface side, and a side opposite to the lower surface side is referred to as an upper surface side. In addition, in the present specification, a plan view means a case where an upper surface or a lower surface (XY plane) of the semiconductor device or the like is viewed in the Z direction. In addition, the aspect ratio and the size relationship between the members in each drawing are merely schematically represented, and do not necessarily coincide with the relationship in the semiconductor device or the like to be actually manufactured. For convenience of description, it is also assumed that the size relationship between the members is exaggerated.

In addition, the semiconductor device exemplified in the following description is applied to, for example, a power conversion device such as an inverter of an industrial or in-vehicle motor. Therefore, in the following description, a detailed description of the same or similar configuration, function, operation, and the like as or to those of a known semiconductor device will be omitted.

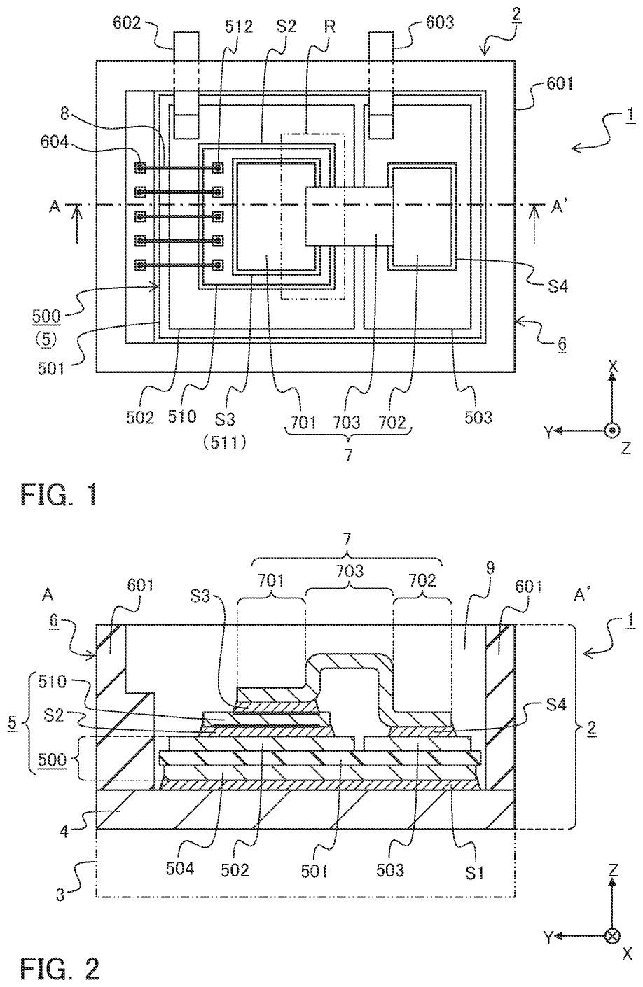

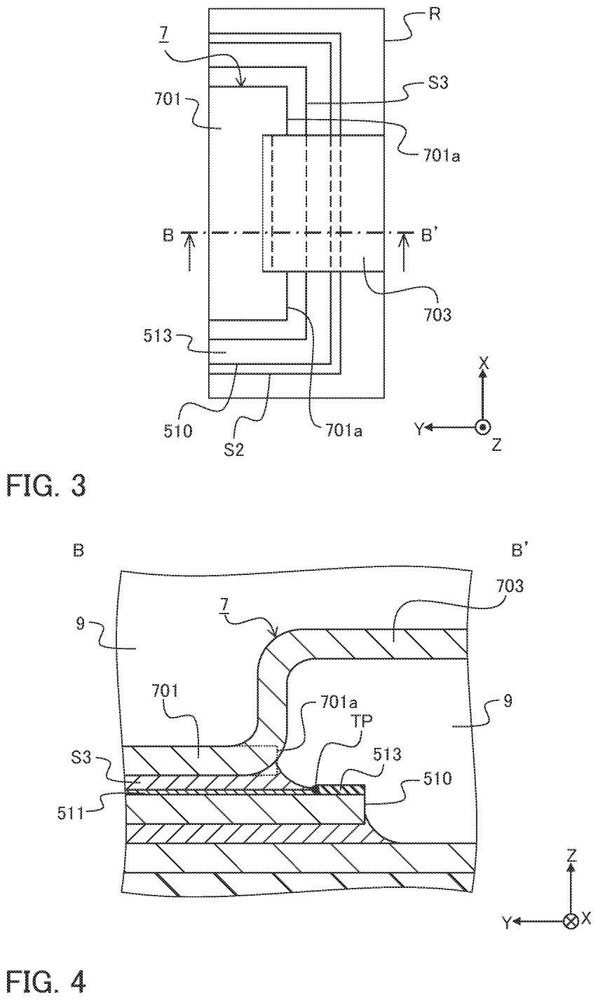

FIG. 1 is a top view illustrating a configuration example of a semiconductor device according to an embodiment. FIG. 2 is a cross-sectional view taken along line A-A′ of the semiconductor device in FIG. 1. FIG. 3 is an enlarged partial top view of a region R in FIG. 1. FIG. 4 is a cross-sectional view taken along line B-B′ of the portion illustrated in FIG. 3. In FIGS. 1 and 3, a sealing material filling a case is omitted. In addition, in FIGS. 2 and 4, hatching indicating a cross section of the sealing material filling the case is omitted.

As exemplified in FIGS. 1 and 2, the semiconductor device 1 according to the present embodiment is configured by disposing a semiconductor module 2 on an upper surface of a cooler 3. Note that the cooler 3 has any configuration with respect to the semiconductor module 2.

The cooler 3 releases heat of the semiconductor module 2 to the outside and has a rectangular parallelepiped shape as a whole. Although not particularly illustrated, the cooler 3 is configured by providing a plurality of fins on a lower surface side of a flat plate-shaped base portion and housing these fins in a water jacket. Note that the cooler 3 is not limited to this configuration and can be changed as appropriate.

The semiconductor module 2 includes a base 4, a circuit board 5, a case 6, a lead 7, bonding materials S1 to S4, bonding wires 8, and a sealing material 9.

The base 4 is a substrate on which the circuit board 5 is mounted, and the base 4 on which the circuit board 5 is mounted is attached to a lower surface of the case 6 with a surface on which the circuit board 5 is mounted facing upward. The case 6 includes a rectangular tubular (a square ring shape) insulating member 601 whose upper surface and lower surface are opened, main terminals 602 and 603 integrated with the insulating member 601, and a plurality of control terminals 604. The circuit board 5 mounted on the base 4 is housed in a hollow portion of the insulating member 601 of the case 6. The base 4 is, for example, a metal plate such as a copper plate and conducts heat generated in the circuit board 5 to the cooler 3. This type of base 4 may be referred to as a heat dissipation plate or a heat dissipation layer. The base 4 that is a heat dissipation plate may be, for example, disposed on the upper surface of the cooler 3 via a thermal conductive material such as a thermal grease or a thermal compound. Note that in the semiconductor module 2, the base 4 may be omitted, and the lower surface (a conductor pattern 504 of a wiring board 500 exemplified in FIG. 2) of the circuit board 5 may be bonded to the cooler 3.

The circuit board 5 includes the wiring board 500 and a semiconductor element 510 mounted on an upper surface of the wiring board 500. The wiring board 500 includes an insulating substrate 501, conductor patterns 502 and 503 provided on an upper surface of the insulating substrate 501, and the conductor pattern 504 provided on a lower surface of the insulating substrate 501. The wiring board 500 may be, for example, a direct copper bonding (DCB) substrate or an active metal brazing (AMB) substrate.

The insulating substrate 501 is not limited to a specific substrate. The insulating substrate 501 may be, for example, a ceramic substrate formed of a ceramic material such as aluminum oxide (Al₂O₃), aluminum nitride (AlN), silicon nitride (Si₃N₄), or composite material of aluminum oxide (Al₂O₃) and zirconium oxide (ZrO₂) The insulating substrate 501 may be, for example, a substrate obtained by molding an insulating resin such as epoxy resin, a substrate obtained by impregnating a base material such as glass fiber with an insulating resin, or a substrate obtained by coating a surface of a flat plate-shaped metal core with an insulating resin.

The conductor patterns 502 and 503 provided on the upper surface of the insulating substrate 501 are conductive members used as wiring members in the circuit board 5, and the conductor pattern 504 provided on the lower surface of the insulating substrate 501 is a conductive member used as a heat dissipation member that conducts heat generated in the circuit board 5 to the base 4. These conductor patterns 502 to 504 are formed of, for example, a metal plate such as copper or aluminum. The conductor pattern 504 provided on the lower surface of the insulating substrate 501 is bonded to the upper surface of the base 4 via the bonding material Si such as solder. The conductor patterns 502 and 503 provided on the upper surface of the insulating substrate 501 may be each referred to as a conductor layer, a conductor plate, or a wiring pattern. The conductor pattern provided on the lower surface of the insulating substrate 501 may be referred to as a heat dissipation layer, a heat dissipation plate, or a heat dissipation pattern.

As described above, the conductor patterns 502 and 503 provided on the upper surface of the insulating substrate 501 are conductive members used as wiring members in the circuit board 5.

In the semiconductor module 2 exemplified in FIGS. 1 to 4, the semiconductor element 510 is mounted on the upper surface of the first conductor pattern 502. In the semiconductor element 510, a first main electrode (not illustrated) provided on the lower surface of the semiconductor element 510 is bonded to the first conductor pattern 502 with the bonding material S2.

A second main electrode 511, control electrodes 512, and an insulating layer 513 electrically insulating these electrodes are formed on the upper surface of the semiconductor element 510. The insulating layer 513 may be a surface protective film such as a passivation film formed on the upper surface of the semiconductor element 510. The second main electrode 511 is electrically connected, via the lead 7, to the second conductor pattern 503 provided on the upper surface of the insulating substrate 501. The lead 7 includes a first bonding portion 701 bonded to the second main electrode 511 of the semiconductor element 510 with the bonding material S3, a second bonding portion 702 bonded to the second conductor pattern 503 with the bonding material S4, and a wiring portion 703 connecting the first bonding portion 701 and the second bonding portion 702. The control electrodes 512 on the upper surface of the semiconductor element 510 are electrically connected, via the bonding wires 8, to the control terminals 604 provided on the case 6.

In the semiconductor module 2 exemplified in FIGS. 1 and 2, the first conductor pattern 502 is electrically connected to the first main terminal 602 provided in the case 6, and the second conductor pattern 503 is electrically connected to the second main terminal 603 provided in the case 6. A method of electrically connecting the first conductor pattern 502 and the first main terminal 602 and electrically connecting the second conductor pattern 503 and the second main terminal 603 may be any of known connection methods, and is not limited to a specific method. In addition, the shapes and positions of the main terminals 602 and 603, the number, positions, and the like of the control terminals 604 in the case 6 are not limited to those illustrated, and can be changed as appropriate. Further, the case 6 of the semiconductor module 2 of the present embodiment may be provided with a third main terminal (not illustrated) and the like.

In the present embodiment, the semiconductor element 510 includes, for example, a reverse conducting (RC)-IGBT element in which the functions of an insulated gate bipolar transistor (IGBT) element and a free wheeling diode (FWD) element are integrated.

Note that the semiconductor element mounted on the upper surface of the wiring board 500 is not limited to a specific one. A semiconductor element as a switching element such as an IGBT or a power metal oxide semiconductor field effect transistor (MOSFET) and a semiconductor element as a diode element such as an FWD may be mounted on the upper surface of the wiring board 500. In addition, a reverse blocking (RB)-IGBT or the like having a sufficient withstand voltage against a reverse bias may be used as the semiconductor element. In addition, the shape of the semiconductor element, the number of the semiconductor elements to be arranged, the location of the semiconductor element to be arranged, and the like can be changed as appropriate. The layout of the conductor pattern as the wiring member provided on the upper surface side of the wiring board 500 is changed according to the type and shape of the semiconductor element to be mounted, the number of the semiconductor elements to be arranged, the location of the semiconductor elements to be arranged, and the like.

When the semiconductor element 510 is an IGBT element, the second main electrode 511 on the upper surface side may be referred to as an emitter electrode, and the first main electrode on the lower surface side may be referred to as a collector electrode. When the semiconductor element 510 is a MOSFET element, the second main electrode 511 on the upper surface side may be referred to as a source electrode, and the first main electrode on the lower surface side may be referred to as a drain electrode. In addition, the control electrode 512 provided on the upper surface of the semiconductor element 510 may include a gate electrode and an auxiliary electrode. For example, the auxiliary electrode may be an auxiliary emitter electrode or an auxiliary source electrode electrically connected to the second main electrode 511 and serving as a reference potential with respect to a gate potential. In addition, the auxiliary electrode may be a temperature sensing electrode that is electrically connected to a temperature sensing unit additionally provided in the semiconductor module 2 and measures the temperature of the semiconductor element 510. Such an electrode (the main electrode 511 and the control electrode 512 including a gate electrode and an auxiliary electrode) formed on the upper surface of the semiconductor element 510 may be generally referred to as an upper surface electrode.

The lead 7 described above is formed by bending a metal plate such as a copper plate, and may be referred to as a lead frame or a metal wiring board. The first bonding portion 701 of the lead 7 is electrically connected, via the bonding material S3, to the second main electrode 511 disposed on the upper surface of the semiconductor element 510. The insulating layer 513 electrically insulating the second main electrode 511 from the control electrodes 512 is formed on the upper surface of the semiconductor element 510. The spread of the bonding material S3 with which the second main electrode 511 and the first bonding portion 701 of the lead 7 are bonded is restricted in a plane (XY plane) at the time of melting by the insulating layer 513 formed so as to surround the second main electrode 511 in plan view.

An end portion of the wiring portion 703 of the lead 7 on the first bonding portion 701 side is connected to one side surface 701a of the first bonding portion 701 and is bent in a direction opposite to a lower surface (in other words, a surface of the first bonding portion 701 facing the second main electrode 511 of the semiconductor element 510) of the first bonding portion 701. Similarly, an end portion of the wiring portion 703 of the lead 7 on the second bonding portion 702 side is connected to one side surface of the second bonding portion 702 and is bent in a direction opposite to a lower surface (in other words, a surface of the second bonding portion 702 facing the conductor pattern 503) of the second bonding portion 702.

The semiconductor element 510, the lead 7, the bonding wires 8, and the like housed in the case 6 are sealed with the sealing material 9. The sealing material 9 may be a single insulating material or a combination of a plurality of types of insulating materials having different compositions (characteristics). For example, the sealing material 9 may include a coating material such as polyamide (PA) coating the surfaces of the semiconductor element 510, the lead 7, and the like, and a filler such as epoxy resin or silicone gel filling the hollow portion in the case 6.

The semiconductor device 1 (semiconductor module 2) according to the present embodiment makes it possible to suppress an increase in stress applied to a triple point TP exemplified in FIG. 4. The triple point TP in the present specification is a point where the bonding material S3, the insulating layer 513 of the semiconductor element 510, and the sealing material 9 are connected to each other in FIG. 4, but is indicated by a rectangular outline that is a boundary between the second main electrode 511 and the insulating layer 513 of the semiconductor element 510 in plan view. Hereinafter, a configuration example of the lead 7 making it possible to suppress an increase in stress applied to the triple point TP will be described.

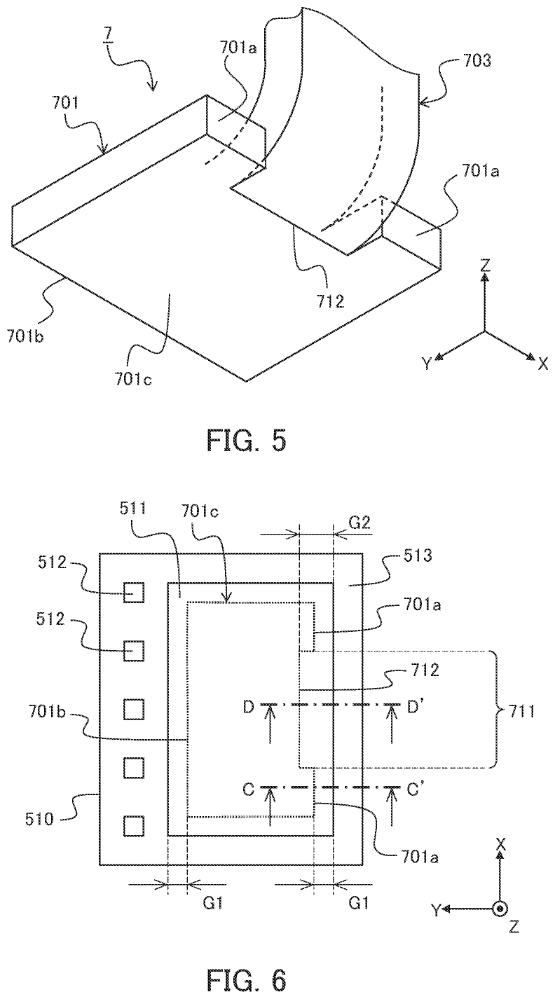

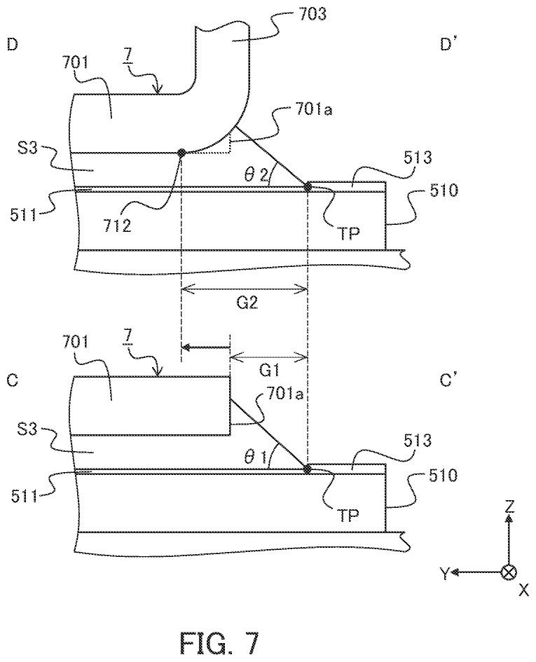

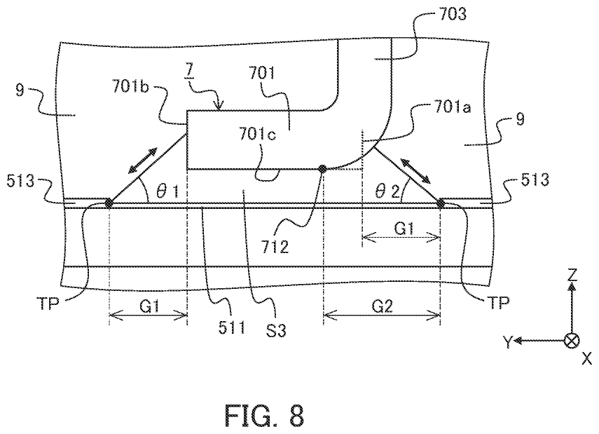

FIG. 5 is a perspective view for explaining a configuration example of a first bonding portion side of a lead according to an embodiment. FIG. 6 is a top view for explaining a connection surface between a second main electrode of a semiconductor element and a first bonding portion. FIG. 7 is a cross-sectional view taken along line C-C′ and a cross-sectional view taken along line D-D′ of the portion illustrated in FIG. 6. FIG. 8 is a cross-sectional view for explaining stress generated in a semiconductor module according to an embodiment. In FIGS. 7 and 8, hatching indicating a cross section of an object is omitted.

As exemplified in FIGS. 5 and 6, in the lead 7 used in the semiconductor module 2 according to the present embodiment, a rising position 712, which is a border between the first bonding portion 701 and the wiring portion 703, in a lower surface 701c of the first bonding portion 701 when the wiring portion 703 is bent in a direction opposite to the lower surface 701c at the first side surface 701a to which the wiring portion 703 is connected in side surfaces of the first bonding portion 701 is displaced in a direction (positive side in the Y direction) of a side surface 701b on a side opposite to the first side surface 701a. Therefore, in the planar shape of the lower surface 701c of the first bonding portion 701 facing the second main electrode 511 of the semiconductor element 510 in plan view, a distance G2 of a connection section 711 that is connected to the wiring portion 703 in a side corresponding to the first side surface 701a from the inner periphery of the insulating layer 513 of the semiconductor element 510 is longer than a distance G1 of a non-connection section that is not the connection section 711 from the inner periphery of the insulating layer 513 of the semiconductor element 510. In FIGS. 5 and 6, the two side surfaces separated by the wiring portion 703 in the first bonding portion 701 are denoted by reference numeral 701a, but in the following description, for convenience, a surface represented by a line (not illustrated) connecting the sides indicating the two side surfaces denoted by reference numeral 701a in plan view is also included in the first side surface 701a. The first side surface 701a of the first bonding portion 701 of the lead 7 according to the present embodiment has two partial side surfaces (non-connection sections) separated by the wiring portion 703 and not connected to the wiring portion 703.

When the first bonding portion 701 of the lead 7 described above and the second main electrode 511 of the semiconductor element 510 are bonded with the bonding material S3, a fillet having a fillet angle θ1 is generated in the non-connection section of the first side surface 701a of the first bonding portion 701 as in the cross-sectional view taken along line C-C′ exemplified in FIG. 7. The fillet angle θ1 is controlled by the distance G1 from the first side surface 701a in the non-connection section to the inner periphery of the insulating layer 513 of the semiconductor element 510, the amount of the bonding material S3, and the like such that the stress generated at the triple point TP by the bonding material S3, the insulating layer 513 of the semiconductor element 510, and the sealing material (not illustrated) falls within a predetermined range.

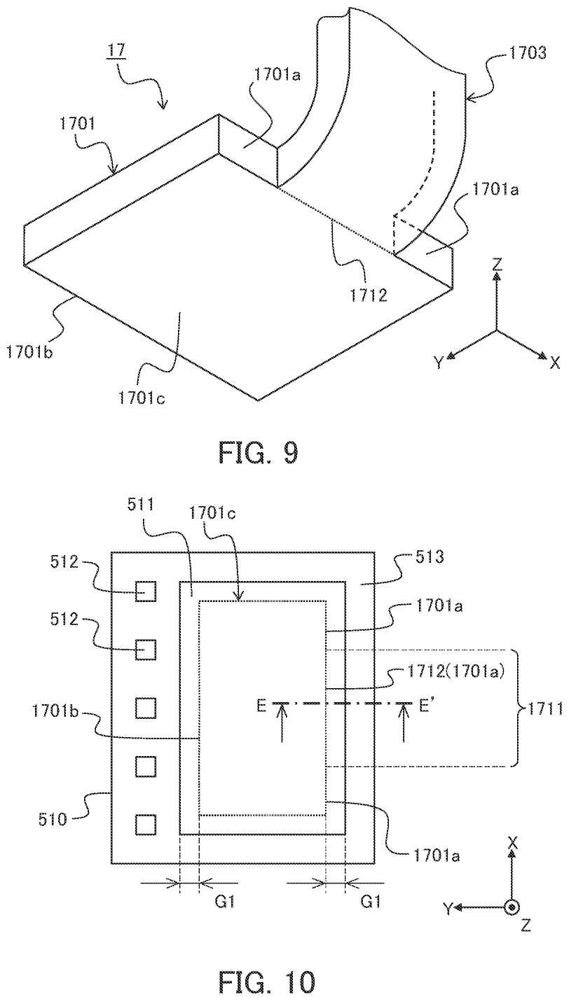

In addition, in the connection section 711 of the first side surface 701a, a fillet having a fillet angle θ2 is generated as in the cross-sectional view taken along line D-D′ exemplified in FIG. 7. At the rising position 712 of the bent of the connection section 711 on the lower surface 701c side, the distance G2 from the inner periphery of the insulating layer 513 of the semiconductor element 510 is longer than the distance G1 in the non-connection section, and therefore, the volume of a space between the bent portion in the wiring portion 703 and the second main electrode 511 of the semiconductor element 510 increases. Therefore, as compared with a conventional example described later with reference to FIGS. 9 to 12, the fillet angle θ2 of the connection section 711 can be reduced while the distance G1 from the non-connection section of the first side surface 701a to the inner periphery of the insulating layer 513 of the semiconductor element 510 is kept short.

For example, as illustrated in FIGS. 6 and 8, in the first bonding portion 701 of the lead 7 used in the semiconductor module 2 of the present embodiment, the second side surface 701b facing the side opposite to the first side surface 701a is also formed so as to be at the distance G1 from the inner periphery of the insulating layer 513 of the semiconductor element 510. In this case, a fillet having the fillet angle θ1 is generated on the second side surface 701b. At this time, the fillet angle θ1 on the second side surface 701b side (and in the non-connection section of the first side surface 701a illustrated in FIG. 7) of the first bonding portion 701 is controlled by the distance G1 from the inner periphery of the insulating layer 513, the amount of the bonding material S3, and the like such that the stress applied to the triple point TP where the bonding material S3, the insulating layer 513 of the semiconductor element 510, and the sealing material 9 are connected to each other falls within a predetermined range.

In addition, in the first bonding portion 701 of the lead 7 according to the present embodiment, the distance G2 from the rising position 712 on the lower surface 701c side in the connection section 711 of the first side surface 701a to the inner periphery of the insulating layer 513 of the semiconductor element 510 is made longer than the distance G1. Therefore, the fillet angle θ2 in the connection section 711 can be made substantially the same as the fillet angle θ1 generated on the side surface at the distance G1 from the inner periphery of the insulating layer 513 of the semiconductor element 510, or smaller than the fillet angle θ1. Therefore, in the semiconductor module 2 according to the present embodiment, it is possible to reduce stress applied to the connection section 711 in the first bonding portion 701 of the lead 7. In addition, the first side surface 701a of the first bonding portion 701 is divided into one connection section 711 and two non-connection sections sandwiching the connection section 711 (separated by the connection section 711) in plan view. Therefore, even when the distance G2 from the insulating layer 513 of the semiconductor element 510 to the rising position 712 of the connection section 711 is made longer than the distance G1 of the non-connection section, it is possible to suppress a decrease in the area of the surface of the first bonding portion 701 in contact with (facing) the second main electrode 511 of the semiconductor element 510.

The operational effects of the semiconductor module 2 according to the present embodiment described above will be described in more detail in comparison with a conventional example with reference to FIGS. 9 to 12.

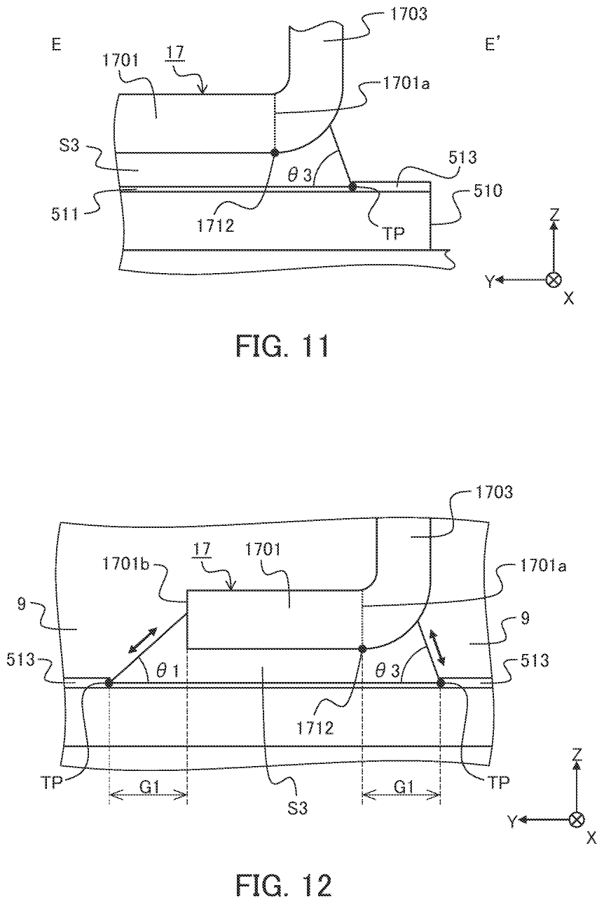

FIG. 9 is a perspective view for explaining the conventional example of a first bonding portion side of a lead. FIG. 10 is a top view for explaining a connection surface between a second main electrode of a semiconductor element and a first bonding portion. FIG. 11 is a cross-sectional view taken along line E-E′ of the portion illustrated in FIG. 10. FIG. 12 is a cross-sectional view for explaining stress generated in a semiconductor module using the lead of the conventional example. In FIGS. 11 and 12, hatching indicating a cross section of an object is omitted.

In the lead 17 exemplified in FIG. 9, similarly to the lead 7 according to the embodiment described above, a wiring portion 1703 is connected to a first side surface 1701a of side surfaces of the first bonding portion 1701 bonded to the second main electrode 511 of the semiconductor element 510 with the bonding material S3. However, a rising position 1712 of the wiring portion 1703 of the lead 17 on a lower surface 1701c side of the first bonding portion 1701 is substantially the same as a position obtained by extending a lower side of the first side surface 1701a. That is, in the lead 17, the shape of the lower surface 1701c of the first bonding portion 1701 facing the second main electrode 511 of the semiconductor element 510 in plan view is rectangular as exemplified in FIG. 10. In this case, in a connection section 1711 connected to the wiring portion 703 in a side corresponding to the first side surface 1701a, the whole of the wiring portion 1703 protrudes to the insulating layer 513 side of the semiconductor element 510 from the first side surface 1701a of the first bonding portion 1071 as exemplified in FIG. 11. Therefore, when the first bonding portion 1701 of the lead 17 and the second main electrode 511 of the semiconductor element 510 are bonded with the bonding material S3, a fillet angle θ3 of a fillet generated in the connection section with the wiring portion 1703 in the first side surface 1701a is larger than the fillet angle θ1 on a second side surface 1701b side (and in a not-illustrated non-connection section of the first side surface 1701a) in the first bonding portion 1701 as exemplified in FIG. 12.

On the other hand, in the lead 7 of the present embodiment, as described above with reference to FIGS. 5 to 8, the rising position 712 of the bent of the wiring portion 703 in the lower surface 701c of the first bonding portion 701 is shifted from the first side surface 701a to which the wiring portion 703 is connected to the second side surface 701b side on the side opposite to the first side surface 701a. Therefore, the amount of protrusion of the wiring portion 703 from the first side surface 701a of the first bonding portion 701 to the insulating layer 513 side of the semiconductor element 510 is smaller than the amount of protrusion of the wiring portion 1703 of the lead 17 of the conventional example. With this configuration, as exemplified in FIG. 8, the fillet angle θ2 generated at the portion of the wiring portion 703 when the first bonding portion 701 of the lead 7 of the present embodiment and the second main electrode 511 of the semiconductor element 510 are bonded with the bonding material S3 can be made substantially the same as the fillet angle θ1 on the second side surface 701b (and in the non-connection section of the first side surface 701a illustrated in FIG. 7) of the first bonding portion 701. Therefore, by using the lead 7 of the present embodiment, it is possible to suppress an increase in the force of pulling the sealing material 9 in the upward direction at an interface between the bonding material S3 and the sealing material 9. That is, in the semiconductor module 2 of the present embodiment, it is possible to suppress an increase in stress applied to the triple point TP where the bonding material S3 bonding the first bonding portion 701 of the lead 7 and the second main electrode 511 of the semiconductor element 510, the insulating layer 513 of the semiconductor element 510, and the sealing material 9 are connected to each other, and it is possible to prolong (improve) the life of the semiconductor module 2.

In addition, as described above with reference to FIGS. 5 and 6, in the lead 7 according to the present embodiment, a decrease in the area of the lower surface 701c is suppressed by shifting only the rising position 712 of the connection section 711 connected to the wiring portion 703 in the first side surface 701a of the first bonding portion 701 to the second side surface 701b side. Therefore, the semiconductor module 2 of the present embodiment can suppress an increase in stress applied to the triple point TP while securing the area of the connection surface of the first bonding portion 701 of the lead 7 with the second main electrode 511 of the semiconductor element 510 to suppress a decrease in electrical characteristics and heat dissipation.

A method of bending the end portion of the wiring portion 703 on the first bonding portion 701 side when the lead 7 according to the present embodiment is manufactured is not limited to a specific method. Known pressing can be applied to bending for the wiring portion 703 of the lead 7.

In addition, the distance from the first side surface 701a to the rising position 712 in the lower surface of the first bonding portion 701 when the lead 7 according to the present embodiment is manufactured is not limited to a specific distance.

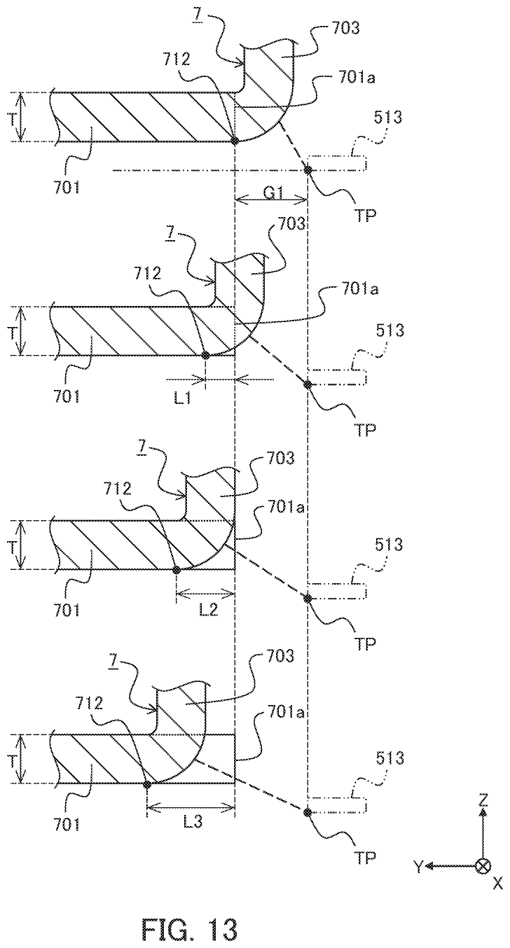

FIG. 13 is a drawing for explaining a relationship between the distance from the first side surface to the rising position in the lower surface of the first bonding portion of the lead and the fillet angle. FIG. 13 schematically illustrates, by thick broken lines, a fillet angle in a case where the rising position 712 is at the same position (that is, the distance 0) as the first side surface 701a as in the conventional example described above, and fillet angles in a case where the distance from the first side surface 701a to the rising position 712 is a distance L1, a distance L2 (>L1), and a distance L3 (>L2). The distance L1 is shorter than a distance corresponding to a thickness T of the first bonding portion 701 of the lead 7. The distance L2 is substantially the same as the distance corresponding to the thickness T of the first bonding portion 701 of the lead 7. The distance L3 is longer than the distance corresponding to the thickness T of the first bonding portion 701 of the lead 7.

When the rising position 712 is shifted in a direction away from the insulating layer 513 of the semiconductor element 510 while the distance G1 from the first side surface 701a of the first bonding portion 701 of the lead 7 to the insulating layer 513 is kept constant, a distance between a surface of the wiring portion 703 continuous from the lower surface 701c of the first bonding portion 701 and the insulating layer 513 increases. Therefore, as the distance from the first side surface 701a to the rising position 712 increases, the fillet angle of the bonding material S3 decreases.

The inventors of the present application examined the relationship between the distance from the first side surface 701a to the rising position 712 and the fillet angle in the lead 7 in which the thickness T of the first bonding portion 701 is 0.5 mm. As a result, by setting the distance from the first side surface 701a to the rising position 712 to 1.0 mm or more, a fillet angle generated at the position of the wiring portion 703 was substantially the same as a fillet angle generated at the first side surface 701a.

As described above, the fillet angle can be reduced by making the distance from the first side surface 701a to the rising position 712 longer than the distance corresponding to the thickness T of the first bonding portion 701. However, due to an increase in the distance from the first side surface 701a to the rising position 712, the area of the lower surface 701c of the first bonding portion 701 decreases, and the connection area with the second main electrode 511 of the semiconductor element 510 decreases. Therefore, the distance from the first side surface 701a to the rising position 712 is preferably set in consideration of the influence of the fillet angle θ2 of the fillet generated at the position of the wiring portion 703 on the stress applied to the triple point TP and the influence of the connection area of the first bonding portion 701 with the second main electrode 511 of the semiconductor element 510 on the electrical and thermal characteristics.

Note that the angle of the bent portion of the wiring portion 703 in the lead 7 according to the present embodiment is not limited to the substantially right angle exemplified in FIGS. 2, 4, 13, and the like, and may be any obtuse angle.

In addition, when a connection portion between the first bonding portion 701 and the wiring portion 703 is bent such that the rising position 712 is closer to the second side surface 701b side than the first side surface 701a, for example, a cut may be made at a boundary between the connection section 711 and the non-connection section in the first side surface 701a.

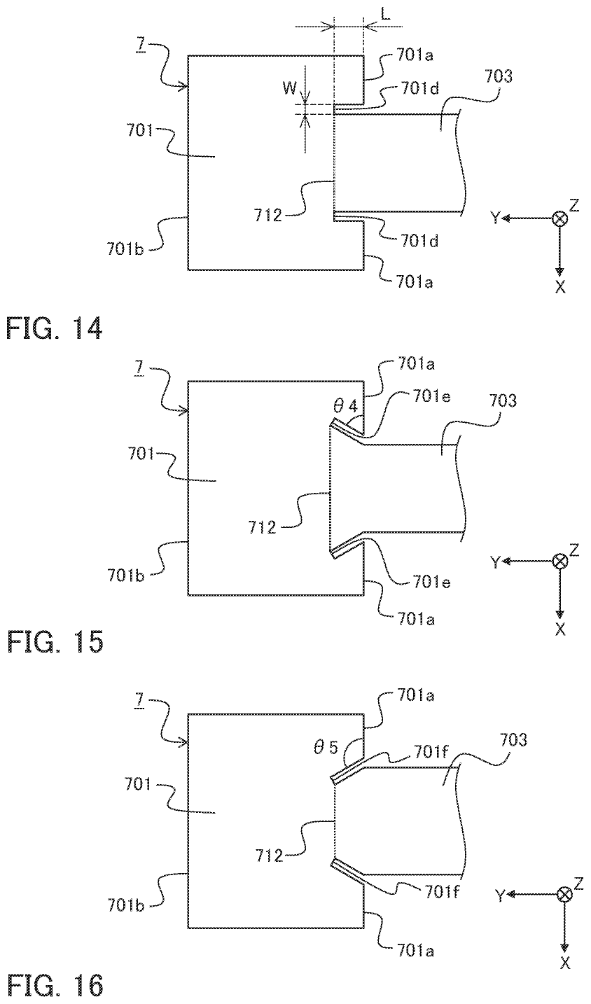

FIG. 14 is a bottom view for explaining a first example of cuts made in the lead. FIG. 15 is a bottom view for explaining a second example of cuts made in the lead. FIG. 16 is a bottom view for explaining a third example of cuts made in the lead. Each of FIGS. 14 to 16 illustrates the first bonding portion 701 and a portion of the wiring portion 703 on the first bonding portion 701 side in the lead 7 before performing bending on the wiring portion 703.

FIG. 14 illustrates an example in which a cut 701d is formed between the wiring portion 703 and an end on the wiring portion 703 side in each of two portions (non-connection sections) of the first side surface 701a separated by the wiring portion 703, and the cut 701d proceeds in a direction (Y direction) orthogonal to the first side surface 701a. A depth L of the cut 701d corresponds to the distance from the first side surface 701a to the rising position 712 described above with reference to FIG. 13. A width W of the cut 701d is not limited to a specific width, but it is preferable to reduce the width W in order to increase the area of the lower surface 701c of the first bonding portion 701. A method of forming the cut 701d is not limited to a specific method.

FIG. 15 illustrates an example in which a cut 701e is formed between the wiring portion 703 and an end on the wiring portion 703 side in each of two portions (non-connection sections) of the first side surface 701a separated by the wiring portion 703, and the cut 701e proceeds in a direction in which a distance between the cuts increases with increasing distance from the first side surface 701a. With the cut 701e described above, for example, the length of the rising position 712 in plan view can be made longer than that in a case where the cut 701d exemplified in FIG. 14 is formed. Therefore, for example, it is considered that a current or heat easily flows from the first bonding portion 701 to the wiring portion 703 beyond the rising position 712. An angle θ4 that is the proceeding direction of the cut 701e is not limited to a specific angle. In addition, the combination of the depth L and the width W of the cut 701e is not limited to a specific combination.

FIG. 16 illustrates an example in which a cut 701f is formed between the wiring portion 703 and an end on the wiring portion 703 side in each of two portions (non-connection sections) of the first side surface 701a separated by the wiring portion 703, and the cut 701f proceeds in a direction in which a distance between the cuts decreases with increasing distance from the first side surface 701a. The cut 701f described above is advantageous, for example, for increasing the area of the lower surface 701c of the first bonding portion 701 in plan view. An angle θ5 that is the proceeding direction of the cut 701f is not limited to a specific angle. In addition, the combination of the depth L and the width W of the cut 701f is not limited to a specific combination.

In addition, in the embodiment described above, the connection portion between the first bonding portion 701 bonded to the second main electrode 511 of the semiconductor element 510 and the wiring portion 703 in the lead 7 has been described. However, the configuration of the connection portion between the first bonding portion 701 and the wiring portion 703 described above may also be applied to, for example, a connection portion between the second bonding portion 702 bonded to the second conductor pattern 503 of the wiring board 500 and the wiring portion 703 in the lead 7.

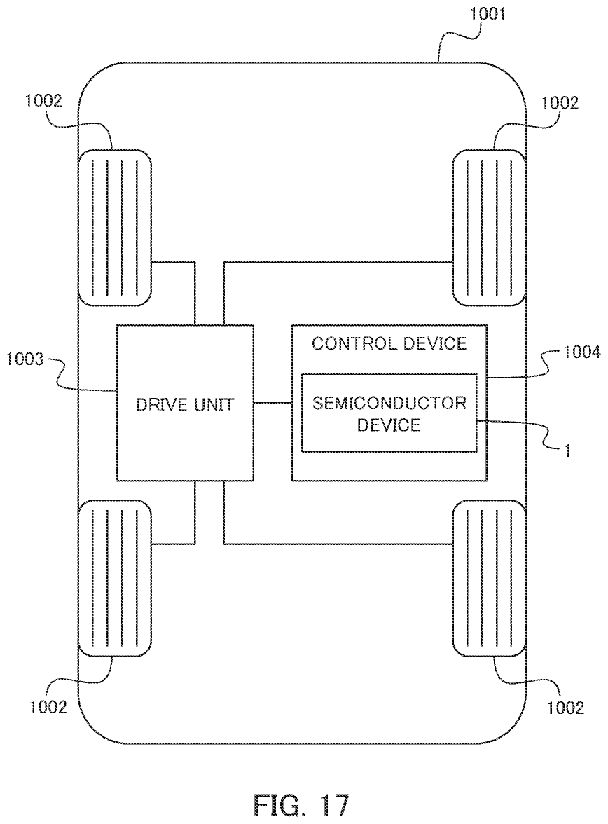

As described above, the semiconductor device 1 including the semiconductor module 2 of the present embodiment can be applied to a power conversion device such as an inverter of an in-vehicle motor. A vehicle to which the semiconductor device 1 according to the present invention is applied will be described with reference to FIG. 17.

FIG. 17 is a schematic plan view illustrating an example of a vehicle to which the semiconductor device according to the present invention is applied. A vehicle 1001 illustrated in FIG. 17 includes, for example, a four-wheeled vehicle including four wheels 1002. The vehicle 1001 may be, for example, an electric vehicle that drives wheels by a motor or the like, or a hybrid vehicle using power of an internal combustion engine in addition to the motor.

The vehicle 1001 includes a drive unit 1003 that applies power to the wheels 1002, and a control device 1004 that controls the drive unit 1003. The drive unit 1003 may include, for example, at least one of an engine, a motor, and a hybrid of an engine and a motor.

The control device 1004 performs control (for example, power control) of the drive unit 1003 described above. The control device 1004 includes the semiconductor device 1 described above. The semiconductor device 1 may be configured to perform power control on the drive unit 1003.

In the semiconductor module 2 of the semiconductor device 1 used for this type of vehicle 1001, when the first bonding portion 701 of the lead 7 described above is bonded to the electrode (for example, the second main electrode 511 of the semiconductor element 510) on the upper surface of the semiconductor element with the bonding material S3, it is possible to suppress an increase in stress and deterioration of electrical and thermal characteristics in the semiconductor module 2 due to thermal history. Therefore, it is possible to reduce the frequency of inspection and replacement of the semiconductor device 1 used for the vehicle 1001.

Note that the vehicle to which the semiconductor device 1 is applied is not limited to the four-wheeled vehicle exemplified in FIG. 17. The vehicle to which the semiconductor device 1 is applied includes, for example, a two-wheeled vehicle and a railway vehicle.

Although the present embodiments and the modifications have been described above, the above-described embodiments and modifications may be wholly or partially combined as another embodiment.

In addition, the present embodiments are not limited to the above-described embodiments and modifications, and various changes, substitutions, and modifications may be made without departing from the spirit of the technical concept. Furthermore, when the technical concept can be realized in another manner by the progress of the technology or another derived technology, the present invention may be implemented using the method. Therefore, the claims cover all embodiments that may be included within the scope of the technical concept.

Feature points in the embodiments described above will be summarized below.

A semiconductor module according to the embodiment includes: a circuit board on which a semiconductor element is mounted; a lead bonded to an electrode on an upper surface of the semiconductor element with a bonding material; and a sealing material that seals the semiconductor element and the lead, in which the lead includes a bonding portion bonded to the electrode and a wiring portion connected to a first side surface of the bonding portion and bent in a direction opposite to a lower surface of the bonding portion facing the electrode of the semiconductor element, a rising position of a bent portion of the wiring portion in the lower surface of the bonding portion is located between a position of the first side surface of the bonding portion and a position of a second side surface of the bonding portion on a side opposite to the first side surface.

In the semiconductor module according to the embodiment, there is a triple point where the bonding material, an insulating layer extending along an outer periphery of the electrode on the upper surface of the semiconductor element, and the sealing material are connected to each other.

In the semiconductor module according to the embodiment, a distance from the first side surface to the rising position in the lower surface of the bonding portion is longer than a distance corresponding to a thickness of the bonding portion.

In the semiconductor module according to the embodiment, the first side surface of the bonding portion of the lead has two non-connection sections that are separated by the wiring portion connected to the bonding portion and are not connected to the wiring portion.

In the semiconductor module according to the embodiment, the bonding portion of the lead has a cut formed between the wiring portion and an end on the wiring portion side in each of the non-connection sections of the first side surface and proceeding in a direction from the first side surface to another side surface.

In the semiconductor module according to the embodiment, the cut proceeds in a direction orthogonal to the first side surface.

In the semiconductor module according to the embodiment, the cut proceeds in a direction in which a distance between the cuts changes with increasing distance from the first side surface.

The semiconductor module according to the embodiment further includes an insulating layer extending around the electrode on the upper surface of the semiconductor element, in which a distance from the first side surface of the bonding portion of the lead to the insulating layer is substantially the same as a distance from at least one side surface of other side surfaces of the bonding portion to the insulating layer.

In the semiconductor module according to the embodiment, the lead includes a second bonding portion connected to an end portion of the wiring portion on a side opposite to a side connected to the bonding portion and bonded to a conductor pattern of the circuit board.

A semiconductor device according to the embodiment includes: the semiconductor module described above; and a cooler disposed on a surface of the circuit board of the semiconductor module on a side opposite to a surface of the circuit board on which the semiconductor element is mounted.

A vehicle according to the embodiment includes the semiconductor module or the semiconductor device described above.

As described above, the present invention has an effect of making it possible to suppress the occurrence of a crack at a triple point where a bonding material that bonds an electrode of a semiconductor element and a lead, an insulating layer extending along an outer periphery of the electrode of the semiconductor element, and a sealing material that seals the semiconductor element and the lead are in contact with each other, and in particular, the present invention is useful for a semiconductor module for industrial use or electrical equipment, a semiconductor device, and a vehicle.

What is claimed is:

1. A semiconductor module, comprising:
a semiconductor element;
a circuit board on which the semiconductor element is mounted;
a lead bonded to an electrode on an upper surface of the semiconductor element with a bonding material; and
a sealing material that seals the semiconductor element and the lead, wherein
the lead includes a first bonding portion having an upper surface and a lower surface that is opposite to the upper surface and is bonded to the electrode, and a wiring portion connected to the first bonding portion, the first bonding portion having a first side surface and a second side surface that face each other between the upper surface and the lower surface, the wiring portion having a bent portion that is connected to the first bonding portion at a side of the first bonding portion at which the first side surface is located, and
the bent portion is bent at a border between the first bonding portion and the bent portion in a direction away from the lower surface of the first bonding portion, the border being located between the first side surface and the second side surface of the first bonding portion in a plan view of the lead.

2. The semiconductor module according to claim 1, further comprising an insulating layer extending along an outer periphery of the electrode on the upper surface of the semiconductor element, wherein
the bonding material, the insulating layer and the sealing material are connected to one another at the same point.

3. The semiconductor module according to claim 1, wherein a distance from the first side surface to the border on the lower surface of the first bonding portion is greater than a thickness of the first bonding portion.

4. The semiconductor module according to claim 1, wherein the first side surface of the first bonding portion has a connection section and two non-connection sections that sandwich the connection section, the connection section being connected to the wiring portion, the non-connection sections being not connected to the wiring portion.

5. The semiconductor module according to claim 4, wherein the first bonding portion of the lead has two cuts respectively formed from the first side surface toward the second side surface of the first bonding portion between the connection section and respective ones of the two non-connection sections.

6. The semiconductor module according to claim 5, wherein the two cuts from the first side surface toward the second side surface respectively extend in a direction orthogonal to the first side surface.

7. The semiconductor module according to claim 5, wherein the two cuts extend so that a distance between the two cuts in the plan view increases with increasing distance from the first side surface.

8. The semiconductor module according to claim 1, further comprising an insulating layer extending around the electrode on the upper surface of the semiconductor element, wherein
a distance from the first side surface of the first bonding portion to the insulating layer is substantially the same as a distance from at least one of side surfaces of the first bonding portion including the second side surface to the insulating layer.

9. The semiconductor module according to claim 1, wherein
the circuit board further having a conductor pattern thereon, and
the lead includes a second bonding portion bonded to the conductor pattern, and being connected to the wiring portion at a side of the wiring portion opposite to a side of the wiring portion where the first bonding portion is connected.

10. A semiconductor device, comprising:
the semiconductor module according to claim 1; and
a cooler disposed on a surface of the circuit board at a side of the circuit board that is opposite to a side where the semiconductor element is mounted.

11. A vehicle comprising the semiconductor module according to claim 1.
